(19) United States
(12) Patent Application Publication
(10) Pub. No.: US 2006/0270110 A1
(43) Pub. Date: Nov. 30, 2006

(54) Method for connecting a semiconductor chip onto an interconnection support

(75) Inventor: Francis Steffen, Saint Maximin (FR)

Correspondence Address: SEED INTELLECTUAL PROPERTY LAW GROUP PLLC, 701 FIFTH AVENUE, SUITE 6300, SEATTLE, WA, 98104-7092, US

(73) Assignee: STMicroelectronics S.A., Montrouge (FR)

(21) Appl. No.: 11/431,135

(22) Filed: May 9, 2006

(30) Foreign Application Priority Data
May 11, 2005 (FR) 05 04700

(51) Int. Cl. H01L 21/58

(52) U.S. Cl. 438/108; 438/125

(57) ABSTRACT

A method electrically connects a semiconductor chip, having contact pads, with an interconnection support, having a substrate and reception pads. The method comprises a step of growing a first metal layer on the contact pads of the chip and a step of growing a second metal layer on the reception pads of the interconnection support, by metal electrodeposition, until the first and the second metal layers meet and form an electrical contact linking the contact pads of the chip and the reception pads of the interconnection support. The method can be applied to the manufacture of electronic cards and electronic modules.

### BACKGROUND OF THE INVENTION

1. Field of the Invention

The present invention relates to the manufacture of electronic modules or electronic cards on flexible or rigid substrates.

The present invention more particularly relates to a method for electrically connecting a semiconductor chip onto an interconnection support, the chip comprising contact pads and the interconnection support comprising a substrate and reception pads.

2. Description of the Related Art

An integrated circuit conventionally comes in the form of a silicon chip which comprises an active side onto which is implanted an integrated circuit region, forming the actual integrated circuit, and contact pads electrically linked to the integrated circuit region. In the applications requiring a high level of integration, the silicon chips are generally bare mounted onto their interconnection supports, without being previously arranged within a protective packaging. In this case, the electrical connection of the contact pads of the chips with reception pads of the interconnection support can be made by ultrasonic wire bonding or by using the “flip-chip” technique.

The assembly of a chip according to the flip-chip technique is schematically shown on FIG. 1. This Figure represents a silicon chip 1 and two contact pads 2, 2′ of the chip in cross-sectional views. The contact pads 2, 2′ are covered by a connection material forming a bump 3, 3′ on the active side of the chip. The connection material is, for example, a tin-lead or tin-silver-copper eutectic, a metal-filled conductive polymer, or a metal electrodeposited onto the chip, for example copper, nickel or gold.

The chip is arranged upside down, with its active face directed downward, on an interconnection support 7. The interconnection support 7 comprises a substrate 6 and reception pads 5, 5′ attached to the substrate, and the contact pads 2, 2′ of the chip are arranged on the reception pads 5, 5′. The assembly and connection of the chip 1 on the interconnection support 7 is made by fusing the bumps 3, 3′ in presence of a source of heat, or by creeping the bumps 3, 3′, applying a mechanical energy to the chip, the techniques most commonly used being the creep by compression or by application of ultrasonic waves.

This assembly and connection method comprises numerous technological variations but has the general drawback of requiring a previous step of forming the bumps 3, 3′ on the chip, to prepare the actual step of connection.

### BRIEF SUMMARY OF THE INVENTION

One embodiment of the present invention relates to a method of assembly and connection of a chip on an interconnection support constituting an alternative to this classical method.

One embodiment of the present invention creates an electrical connection between a contact pad of a silicon chip and a reception pad of an interconnection support, by growing a first metal layer on the contact pad and a second metal layer on the reception pad until both layers meet.

More particularly, the present invention provides a method for electrically connecting a semiconductor chip with an interconnection support, the chip comprising contact pads, the interconnection support comprising a substrate and reception pads, and the method comprising a step of growing a first metal layer on the contact pads of the chip and a step of growing a second metal layer on the reception pads of the interconnection support, by electrodeposition of metal, until the first and the second metal layers meet and form an electric contact linking the contact pads of the chip and the reception pads of the interconnection support.

Preferably, the step of growing the first metal layer and the step of growing the second metal layer are performed simultaneously.

According to one embodiment, the method comprises the steps of: applying a treatment to the contact pads of the chip to make them compatible with the metal electrodeposition, and forming the reception pads of the interconnection support with a material compatible with the metal electrodeposition or applying a treatment to the reception pads to make them compatible with the metal electrodeposition.

According to one embodiment, the metal layers formed by electrodeposition are in a material chosen in the group comprising copper, nickel and gold.

According to one embodiment, before the electrodeposition of metal, the reception pads of the interconnection support comprise only a trace of a material compatible with the metal electrodeposition, and the reception pads are totally formed only after growing the second metal layer.

According to one embodiment, the interconnection support comprises conductive paths extending from the reception pads, and wherein, before the metal electrodeposition, the conductive paths comprise only a trace of a material compatible with the metal electrodeposition, and are totally formed only after growing the second metal layer.

According to one embodiment, the trace of material compatible with the metal electrodeposition comprises a polymer material.

According to one embodiment, an electrical potential different from zero is applied to the reception pads of the interconnection support and the contact pads of the chip during the metal electrodeposition.

According to one embodiment, during the metal electrodeposition, an electrical potential is applied to a semiconductor substrate of the chip, and the contact pads of the chip receive the electrical potential through antistatic PN junctions linking the contact pads to the semiconductor substrate.

According to one embodiment, the method comprises a step of providing, in the chip, contact pads without antistatic junctions and insulated from the semiconductor substrate by a well made of an electrically insulating material, so that no significantly thick metal deposit produces on such contact pads during the metal electrodeposition.

According to one embodiment, during the metal electrodeposition, the chip is maintained on the interconnection support by a layer of insulating material which does not cover the contact pads of the chip that are to receive the first metal layer.

### BRIEF DESCRIPTION OF THE SEVERAL VIEWS OF THE DRAWINGS

These and other advantages and features of the present invention will be presented in greater detail in the following description of the method according to the invention, in relation, but not limited to the following figures:

FIG. 1 previously described shows a classical method of assembly and connection of a chip onto an interconnection support according to the flip-chip technique.

FIG. 2A, 2B respectively represent, in top views, a silicon chip and an interconnection support before the assembly and connection of the chip onto the interconnection support according to the method of the invention.

FIG. 3A is a cross-sectional view showing a step of the method according to the invention at an intermediary stage of development.

FIG. 3B shows the step of FIG. 3A at an advanced or final stage of development.

FIG. 4 is a schematic cross-sectional view of the chip and shows an aspect of the method of the invention.

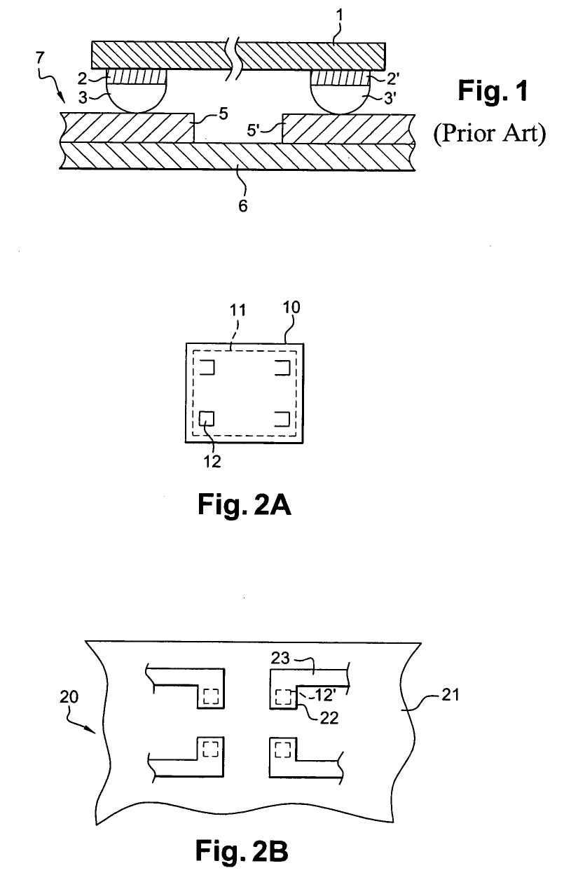

### DETAILED DESCRIPTION OF THE INVENTION

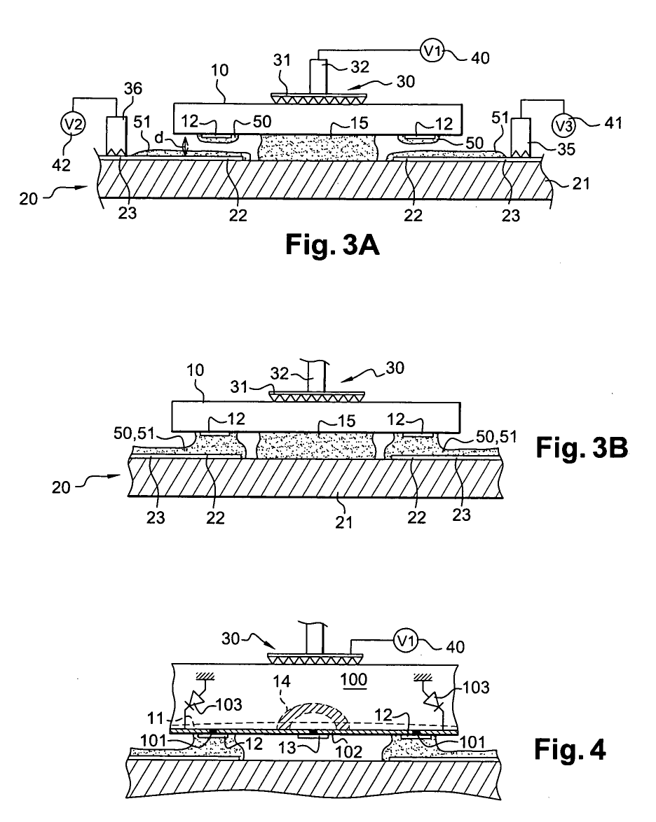

As mentioned above, one embodiment of the present invention provides the electrical connection of a silicon chip to an interconnection support by growing a first metal layer on the contact pads of the chip, and a second metal layer on the reception pads of the interconnection support, until both layers meet. The step of growing the two metallic layers is achieved by metal electrodeposition and is shown on FIGS. 3A, 3B which will be described hereinafter. The preparatory steps preceding the step of electrodeposition will be described first.

FIG. 2A represents a silicon chip 10 in top view before the implementation of the method according to one embodiment of the invention. The top side or active side of the chip 10 comprises an integrated circuit region 11 implanted in the silicon, and contact pads 12. The latter are usually thin, generally between 0.1 to 1 micrometer, and made of aluminum. They are connected to the integrated circuit region 11 thanks to openings (not shown) made through a protective layer (passivation) deposited onto the surface of the chip.

Preferably, the contact pads 12 are submitted to a surface treatment ensuring the adhesion of a metal during the step of electrodeposition. This surface treatment comprises, for example, a deoxidation of the aluminum or the deposit of a thin adhesion layer, for example in nickel, zinc-nickel or palladium. It can be performed when the chip is still attached to the silicon wafer from which it stems, before cutting the wafer into individual chips. This previous step of treatment is therefore substantially identical to the step of treatment preceding the formation, by electrodeposition of a connection material, of the bumps using the flip-chip technique.

FIG. 2B is a partial top view of an interconnection support 20 intended to receive the chip 10. The interconnection support 20 comprises a dielectric substrate 21, onto which conductive pads or reception pads 22 intended to receive the contact pads 12 of the chip have been formed, the location provided for the contact pads 12 being indicated by a dotted line 12′. The pads 22 are end portions of conductive paths 23 which are intended to link the chip to other components. These other components can be other silicon chips which will be collectively connected to the interconnection support during the step of metal electrodeposition described hereinafter, the step can be thus simultaneously applied to a plurality of chips.

The method can be implemented with two types of interconnection supports, which will be referred to as “A” type and “B” type.

The interconnection support 20 is of the A type if it comprises pads 22 and conductive paths 23 completely formed. The support is for example a printed circuit comprising an epoxy substrate and paths in copper resulting from the etching of a sheet of copper. However, an interconnection support of the A type can also comprise a substrate of the “flex” type, that is, a flexible substrate in a polymer material onto which pads and conductive paths have been formed by metal electrodeposition.

The interconnection support 20 is of the B type if it comprises pads and paths which are in an “embryonic” state, usually called “traces”, which only constitute an adhesion layer for a metal electrodeposition in order to obtain pads and paths completely formed. This technique is generally performed with substrates of the “flex” type and the materials forming the traces are generally conductive inks deposited by ink jet. The substrates of the “flex” type are commonly used in the industry and are for example in polyethylene. They are usually thin, for example 50 micrometers. Moreover, the conductive inks used to form the traces are generally metal-loaded polymer compositions (copper, silver, gold . . . ) or carbon-loaded polymer compositions (graphite).

The interconnection support, if it is of the B type, does not require, in principle, a preparatory step before the step of electrodeposition, the traces being provided for that purpose. The interconnection support, if it is of the A type, preferably receives, like the contact pads of the chip, a deoxidation treatment or an adhesion layer forming a metallic barrier compatible with the electrodeposition. This treatment is preferably applied to the reception pads 22 only and on the contrary, the conductive paths 23 are covered by a protection layer (a varnish for example) preventing metal deposition, unless it is desired to increase the thickness of the paths to improve their electrical conductivity.

FIG. 3A shows the step of the actual connection, that constitutes an important step of the method according to one embodiment of the invention.

At first, the chip is arranged upside down, that is with its active face directed towards the interconnection support, and its contact pads 12 are substantially arranged in front of the reception pads 22 of the support. Therefore the arrangement of the chip is substantially the same than the one provided during a flip-chip connection, but here a distance d is kept between its contact pads 12 and the reception pads 22 of the interconnection support. This distance d is preferably of the order of about ten micrometers to a few tens of micrometers. Maintaining the chip 10 in the position represented is achieved, for example by interposing a layer of electrically insulating material 15, and preferably adhesive, between the chip 10 and the substrate 21, for example a non-conductive polymer glue.

The whole is immersed in an electrolytic bath (not shown) comprising metallic ions, for example a bath of copper, nickel, or even a bath of gold. An electric polarization electrode 30 linked to a power supply 40 providing an electrical potential V1 of a few Volts, is applied on a face of the chip 10, preferably its rear face. The electrode 30 is of a classical type, used for the electrodeposition of the flip-chip connection bumps. It comprises for example a contact board 31 provided with pyramid-shaped tips which are applied onto the rear face of the chip. The contact board 31 is attached to a conductive tube (not shown) linked to the power supply 40, the tube sliding in a sleeve 32 comprising a spring (not shown) returning the contact board 31 toward the chip 10.

Similarly, polarization electrodes 35, 36 with claws or clamps linked to sources 41, 42 of electrical potentials V2, V3 are applied to conductive paths 23 (substrate of the A type) or on the traces of conductive paths 23 (substrate of the B type) of the interconnection support 20. Although it does not appear on the schematic representation of FIG. 3A, the areas of application of the polarization electrodes 35, 36 are usually located at the periphery of the interconnection support 20 and are then removed by cutting the substrate at the end of the metal deposition.

Under the effect of the electrical potentials V1, V2, V3, metallic ions coat the polarized conductive regions, i.e., the contact pads 12 of the chip 10 (the rest of the chip 10 being conventionally covered by a passivation layer) as well as the reception pads 22 (interconnection support of the A type ) or the traces of the conductive paths 23 (interconnection support of the B type).

Thus a first metal layer 50 forms on the contact pads 12 and a second metal layer 51 simultaneously forms on the reception pads 22 or on the traces of the contact pads and the traces of conductive paths.

The metal deposition by migration of metallic ions causes the appearance of an electrolysis current and the speed of growth of the metallic layers 50, 51 is a function of the potentials V1, V2, V3. These potentials can be identical (in that case one can use a single supply voltage). However, it is possible to provide a potential V1, different from the potentials V2, V3, in order to impose different speeds of growth to the layers 50, 51 so as to deposit more metal on one side or the other. It can be preferable, for example, when the interconnection support is of the B type and that it is desired to deposit a significant thickness of metal on the traces to obtain reception pads 22 and conductive paths 23 of low resistivity. The growth of the layers 50, 51 can also be performed not simultaneously, by applying the electrical potentials at different times.

At the end of the growing process, the metal layers 50, 51 meet in the regions located between the contact pads 12 and the reception pads 22, as it is represented in FIG. 3B. An electric contact of excellent quality is thus obtained between the chip and the interconnection support.

The metal deposition only lasts a few minutes and makes it possible to deposit conductive layers 50, 51 of a thickness comprised between about ten to some tens of micrometers each, preferably of the order of 10 to 15 micrometers.

One important advantage of this method compared to the flip-chip method is that the two classical steps of forming the bumps on the chip and of connecting the chip to the interconnection support are gathered into a combined step of metal electrodeposition and electrical connection. In the case of an interconnection support of the B type, the three process steps that are usually performed at different times, and even in different places, are here gathered into one combined step, that is the step of forming the reception pads and the conductive paths of the interconnection support, the step of forming the bumps on the chip and the step of connecting the chip on the interconnection support.

The method of the invention is naturally susceptible of various embodiments. Particularly, the interconnection support can be at the same time of the A type and of the B type, i.e., it can have completely formed paths 23 and traces of reception pads 22. In this case, the paths 23 are covered by a protection layer, as for a substrate of the A type.

The invention can also be implemented using a method of metal deposition not requiring the electrical polarization of the areas to be metallized. This type of method, known as “electroless” is also commonly used in the industry. In this case, the areas that are to receive the metal layers 50, 51 are coated with an adhesion layer having electronegativity or electropositivity properties compatible with the metal electrodeposition. The metal deposition remains, by its nature, a galvanic deposit, but has a slower speed of growth determined by the electronic affinities between the adhesion layer and the metallic ions in solution. The metal layers 50, 51 deposited are for example in copper and the adhesion layers in copper or nickel. Nickel and copper grow very efficiently with the electroless method, and also allow layers some tens of micrometers thick to be formed. However, the process is more difficult to control for thin layers, and has some drawbacks (formation of precipitates for example) which are compensated by simpler conditions of implementation (no polarization electrodes).

The present invention is also susceptible of various applications. The invention is notably applicable to the manufacture of small electronic modules, particularly contactless electronic modules intended to be integrated within various contactless portable objects, like contactless chip cards, contactless electronic badges, contactless electronic tags, etc. In that case, the chip 10 is for example a contactless integrated circuit of the PICC type (“proximity inductive coupling circuit”) as described in the ISO 14443 standard (the term “contactless” conventionally designates an integrated circuit provided to emit and/or receive data by means of an antenna). The paths 23 of the interconnection support, instead of linking the chip to other components, form an antenna coil which can have a plurality of coplanar coils surrounding the chip 10. The chip 10 can also be an UHF contactless integrated circuit and the conductive paths 23 can form an UHF antenna without coil.

FIG. 4 is a magnification of FIG. 3A which represents very schematically a cross-sectional view of the internal structure of the silicon chip 10. The chip comprises a substrate 100 and the integrated circuit region 11, embedded on the front face, does not extend deeply into the substrate. The contact pads 12 are linked to the active region by metallized openings 101 going right through an insulating layer 102 which covers the integrated circuit region 11. The pads 12 are also linked to the core of the substrate 100 by means of PN junctions 103 which form antistatic diodes arranged in the blocking direction in relation to stray electrical charges that may accumulate on the pads 12. Therefore, such diodes prevent stray electrical charges from entering the core of the substrate 100 and causing increases of electrical potential (able to reach thousands of Volts) which may damage the integrated circuit region 11. Another advantage of the antistatic diodes 103 is to allow the potential V1 applied on the rear face of the chip to reach the contact pads 12, since the diodes are then biased in the conducting direction.

According to an optional embodiment of the invention, the chip 10 comprises one or several contact pads 13 (only one being shown) which are linked to the integrated circuit region 11 but are not intended to be connected to the interconnection support. On the contrary, such contact pads must be inaccessible when the chip is mounted on the interconnection support. Usually, they are test pads used by the manufacturer to perform electrical test patterns in order to reject the defective chips at the end of the collective manufacturing process on silicon “wafer”.

It is advisable that the metal layer 50 does not form on the test pads 13 during the electrodeposition phase, because it may lead to unintentional connections of the pads 13 with conductors of the interconnection support.

To this purpose, a protective material can be deposited onto the pads 13 but it implies an additional step of treatment after the test step. But it can also be desired to perform all the manufacturing steps, including the preparatory steps for the electrodeposition, before the test step.

Another solution is to use the insulating material 15 (FIG. 3A) to cover the pads 13 but the insulating material is preferably arranged in the center of the chip whereas the contact pads 13 are preferably located at the periphery of the chip, near the “normal” contact pads 12.

The invention still provides another solution consisting in not linking the pads 13 in the core of the substrate 100 to the antistatic diodes. On the contrary, the contact pads 13 are electrically insulated from the core of the substrate 100 by an insulating well 14, for example a well in silicon dioxide. In these conditions, the electrical potential V1 applied to the substrate 100 does not reach the pads 13 and they do not attract the metallic ions (or not much), so that no metal deposit of significant thickness appears on the pads 13.

It can be noted that the absence of antistatic diodes is not problematic for the pads 13 because they are not likely to receive significant electrostatic discharges. Indeed, the pads 13 are used in such working conditions that the risks for the electrical charges to accumulate are considerably reduced compared to the operating conditions of the chip after being mounted onto the interconnection support and after the support is integrated in an equipment.

From the foregoing it will be appreciated that, although specific embodiments of the invention have been described herein for purposes of illustration, various modifications may be made without deviating from the spirit and scope of the invention. Accordingly, the invention is not limited except as by the appended claims.

1. A method for electrically connecting a semiconductor chip with an interconnection support, the chip including contact pads, and the interconnection support including a substrate and reception pads, the method comprising:
growing a first metal layer on the contact pads of the chip; and
growing a second metal layer on the reception pads of the interconnection support, by metal electrodeposition, until the first and the second metal layers meet and form an electrical contact linking the contact pads of the chip and the reception pads of the interconnection support.

2. The method according to claim 1, wherein the step of growing the first metal layer and the step of growing the second metal layer are performed simultaneously.

3. The method according to claim 1, comprising the steps of:
applying a treatment to the contact pads of the chip to make the contact pads compatible with the metal electrodeposition, and
forming the reception pads of the interconnection support with a material compatible with the metal electrodeposition or applying a treatment to the reception pads to make the reception pads compatible with the metal electrodeposition.

4. The method according to claim 1, wherein the metal layers formed by electrodeposition are each of a material chosen in the group comprising copper, nickel and gold.

5. The method according to claim 1, wherein, before the metal electrodeposition, the reception pads of the interconnection support comprise only a trace of a material compatible with the metal electrodeposition, and the reception pads are totally formed only after growing the second metal layer.

6. The method according to claim 5, wherein the interconnection support comprises conductive paths extending from the reception pads, and wherein, before the metal electrodeposition, the conductive paths comprise only a trace of a material compatible with the metal electrodeposition, and are totally formed only after growing the second metal layer.

7. The method according to claim 5, wherein the trace of material compatible with the metal electrodeposition comprises a polymer material.

8. The method according to claim 1, wherein an electrical potential different from zero is applied to the reception pads of the interconnection support and the contact pads of the chip during the metal electrodeposition.

9. The method according to claim 1, wherein, during the metal electrodeposition, an electrical potential is applied to a semiconductor substrate of the chip and the contact pads of the chip receive the electrical potential through antistatic PN junctions linking the contact pads to the semiconductor substrate.

10. The method according to claim 9, comprising:
providing, in the chip, an additional contact pad without antistatic junctions; and
insulating the additional contact pad from the semiconductor substrate by a well made of an electrically insulating material, so that no significantly thick metal deposit produces on the additional contact pad during the metal electrodeposition.

11. The method according to claim 1, wherein, during the metal electrodeposition, the chip is maintained on the interconnection support by a layer of insulating material which does not cover the contact pads of the chip which are to receive the first metal layer.

12. A method, comprising:
forming a semiconductor chip including a contact pad;
forming an interconnection support including a substrate and a reception pad; and
electrically connecting the semiconductor chip with the interconnection support by electrodepositing a metal layer between the reception pad and contact pad until the metal layer forms an electrical contact linking the contact pad and the reception pad.

13. The method according to claim 12, wherein the electrodepositing step includes simultaneously electrodepositing a first metal layer on the contact pad and a second metal layer on the reception pad until the first and second metal layers meet and form the electrical contact.

14. The method according to claim 12, further comprising:
applying a treatment to the contact pad to make the contact pad compatible with the electrodepositing step; and
forming the reception pad with a material compatible with the electrodepositing step or applying a treatment to the reception pad to make the reception pad compatible with the electrodepositing step.

15. The method according to claim 12, wherein, before the electrodepositing step, the reception pad includes only a trace of a material compatible with the electrodepositing step, and the reception pad is totally formed only after the electrodepositing step.

16. The method according to claim 15, wherein the interconnection support comprises a conductive path extending from the reception pad, and wherein, before the electrodepositing step, the conductive path comprises only a trace of a material compatible with the electrodepositing step, and are totally formed only after the electrodepositing step.

17. The method according to claim 15, wherein the trace of material compatible with the electrodepositing step comprises a polymer material.

18. The method according to claim 12, wherein the electrodepositing step includes applying an electrical potential different from zero to the reception pad and the contact pad.

19. The method according to claim 12, wherein, during the electrodepositing step, an electrical potential is applied to a semiconductor substrate of the chip and the contact pad receives the electrical potential through an antistatic PN junction linking the contact pad to the semiconductor substrate.

20. The method according to claim 19, comprising:
providing, in the chip, an additional contact pad without an antistatic junction; and
insulating the additional contact pad from the semiconductor substrate by a well made of an electrically insulating material, so that no significantly thick metal deposition is produced on the additional contact pad during the metal electrodeposition.

21. The method according to claim 1, wherein, during the electrodepositing step, the chip is maintained on the interconnection support by a layer of insulating material which does not cover the contact pad.

22. A method, comprising:
forming a semiconductor chip including a contact pad;
forming an interconnection support including a substrate and a reception pad;
forming an insulating layer that extends completely between the semiconductor chip and the interconnection support; and
forming an electrical contact linking the contact pad and the reception pad while the insulating layer maintains the semiconductor chip at a distance from the interconnection support.

23. The method according to claim 22, wherein the step of forming the electrical contact includes simultaneously electrodepositing a first metal layer on the contact pad and a second metal layer on the reception pad until the first and second metal layers meet and form the electrical contact.

24. The method according to claim 23, further comprising:
applying a treatment to the contact pad to make the contact pad compatible with the electrodepositing step; and
forming the reception pad with a material compatible with the electrodepositing step or applying a treatment to the reception pad to make the reception pad compatible with the electrodepositing step.

25. The method according to claim 23, wherein, before the electrodepositing step, the reception pad includes only a trace of a material compatible with the electrodepositing step, and the reception pad is totally formed only after the electrodepositing step.

26. The method according to claim 25, wherein the interconnection support comprises a conductive path extending from the reception pad, and wherein, before the electrodepositing step, the conductive path comprises only a trace of a material compatible with the electrodepositing step, and are totally formed only after the electrodepositing step.

27. The method according to claim 25, wherein the trace of material compatible with the electrodepositing step comprises a polymer material.

28. The method according to claim 23, wherein the electrodepositing step includes applying an electrical potential different from zero to the reception pad and the contact pad.

29. The method according to claim 23, wherein, during the electrodepositing step, an electrical potential is applied to a semiconductor substrate of the chip and the contact pad receives the electrical potential through an antistatic PN junction linking the contact pad to the semiconductor substrate.

30. The method according to claim 29, comprising:
providing, in the chip, an additional contact pad without an antistatic junction; and
insulating the additional contact pad from the semiconductor substrate by a well made of an electrically insulating material, so that no significantly thick metal deposition is produced on the additional contact pad during the metal electrodeposition.
